(19) United States
(12) Patent Application Publication
(10) Pub. No.: US 2020/0044198 A1
(43) Pub. Date: Feb. 6, 2020

(54) LIQUID CRYSTAL DISPLAY (LCD) PANEL, LCD AND MANUFACTURING METHOD THEREOF

(71) Applicant: Wuhan China Star Optoelectronics Semiconductor Display Technology Co., Ltd., Wuhan, Hubei (CN)

(72) Inventor: Sihang BAI, Shenzhen, Guangdong (CN)

(73) Assignee: Wuhan China Star Optoelectronics Semiconductor Display Technology Co., Ltd., Wuhan, Hubei (CN)

(21) Appl. No.: 15/735,879

(22) PCT Filed: Aug. 17, 2017
(86) PCT No.: PCT/CN2017/097754

§ 371 Date: Dec. 12, 2017

(30) Foreign Application Priority Data
Jul. 12, 2017 (CN) 201710565739.0

(51) Int. Cl. H01L 51/56; H01L 51/00; H01L 51/52; H01L 21/768; H01L 21/67

(52) U.S. Cl. CPC H01L 51/56; H01L 51/0097; H01L 21/67075; H01L 21/76894; H01L 51/5256

(57) ABSTRACT

A display panel and the manufacture method thereof, a display device, a manufacturing method of a display panel comprising the following steps. Providing a substrate. Patterning on an edge side of the substrate to form a recessed structure on the substrate. Depositing sequentially a flexible substrate and a stacking structures on the patterning substrate. Peeling the substrate and package to form the display panel. The invention effectively offset warpage of the edge side of the flexible substrate. That improves the surface which faraway the substrate of the flexible substrate are more flat, and the film uniformity of the flexible substrate so that enhance the stability and the yield of the flexible display device.

### BACKGROUND OF THE INVENTION

### 1. Field of the Invention

The present invention relates to the liquid crystal display (LCD), and in particular, to an LCD panel and a manufacturing method thereof, and a LCD device.

### 2. Description of Related Art

Organic light emitting diode (OLED) devices have a lot of advantage, for example self-luminous, simple structure, low cost, view field, high color saturation, fast reaction speed, light and thin and flexible so that widely used for intelligent products, for example the mobile phone, wearable products. People has more requirement to the performance of the OLED with the OLED panel are applied to large-scale commercial, for example low voltage, high brightness, high efficiency, low energy consumption, long lifetime, high stability and so on. Based on the requirement of OLED as above, enhance the efficiency and the stability of the OLED is an important issue.

For enhancing the stability of the OLED, researcher especially focused on improve the structure of OLED. Currently, flexible active-matrix organic light emitting diode is made by polyimide (PI) substrate. The probability morphology of the edge side maybe effective the late TFT film structure, or even effective the electric performance of the TFT. Some researcher also used double PI layer to flatten the flexible substrate, but this method need to coat PI layer twice, it make the manufacture complex and high cost.

### SUMMARY OF THE INVENTION

The present invention provides a display panel and the manufacture method thereof and a display device to effectively offset warpage of the edge side of the flexible substrate. That improves the surface which faraway the substrate of the flexible substrate are more flat, and the film uniformity of the flexible substrate so that enhance the stability and the yield of the flexible display device.

An exemplary embodiment of the present disclosure provides a manufacturing method of a display panel of a display device comprising the following steps. Providing a substrate. Patterning on an edge side of the substrate to form a recessed structure on the substrate. Depositing sequentially a flexible substrate and a stacking structures on the patterned substrate. The stacking structures comprising an active array layer and an organic emission layer depositing sequentially on the flexible substrate. The flexible substrate is selectively made of polyimide or polyethylene terephthalate. Peeling the substrate and package to form the display panel

Another exemplary embodiment of the present disclosure provides a manufacturing method of a display panel comprising the following steps. Providing a substrate. Patterning on an edge side of the substrate to form a recessed structure on the substrate. Depositing sequentially a flexible substrate and a stacking structures on the patterning substrate. Peeling the substrate and package to form the display panel.

Another exemplary embodiment of the present disclosure provides a flexible display panel comprising a flexible substrate, a stacking structures and an encapsulating layer. The flexible substrate has a downwardly projection portion on an edge side. The stacking structures forming on the flexible substrate. The encapsulating layer forming on the stacking structures.

In sum, the advantages of the instant disclosure provide a display panel and the manufacture method thereof, a display device. A recessed structure is provided on the edge side of the substrate, the recessed structure offset warpage of the edge side of the flexible substrate to achieve the surface which faraway the substrate of the flexible substrate are more flat. And the film uniformity of the flexible substrate so that enhance the stability and the yield of the flexible display device. Comparing to the structure of double PI layer can reduce one step for coating the PI layer, and let the manufacture method more easily.

### BRIEF DESCRIPTION OF THE DRAWINGS

FIG. 1 is a flow chart showing a manufacturing method of a display panel according to an embodiment of the present invention;

FIG. 2 is a schematic diagram side view of a pattern formed on the substrate according to an embodiment of the present invention;

FIG. 3 is a schematic diagram top view of a pattern formed on the substrate according to an embodiment of the present invention

FIG. 4 is a schematic diagram top view of a pattern formed on the substrate according to another embodiment of the present invention

FIG. 5 is a schematic diagram of a display panel according to an embodiment of the present invention; and

FIG. 6 is a schematic diagram of a display device according to an embodiment of the present invention.

### DETAILED DESCRIPTION OF THE PREFERRED EMBODIMENTS

Embodiments disclosed in the instant disclosure are illustrated via specific examples as follows, and people familiar in the art may easily understand the advantages and efficacies of the instant disclosure by disclosure of the specification. The instant disclosure may be implemented or applied by other different specific examples, and each of the details in the specification may be applied based on different views and may be modified and changed under the existence of the spirit of the instant disclosure. The figures in the instant disclosure are only for brief description, but they are not depicted according to actual size and do not reflect the actual size of the relevant structure. The following embodiments further illustrate related technologies of the instant disclosure in detail, but the scope of the instant disclosure is not limited herein.

Like reference numerals refer to like elements throughout. In the drawings, the dimensions and size of each structure are exaggerated, omitted, or schematically illustrated for convenience in description and clarity. It will be understood that although the terms of first, second, and three are used herein to describe various elements or signals, these elements or signals should not be limited by these terms. Terms are only used to distinguish one component from other components, or one signal from other signals. Therefore, a component referred to as a first component in one embodiment can be referred to as a second component in another embodiment. The terms of a singular form may include plural forms unless referred to the contrary. In addition, the meaning of ‘comprise’, ‘include’, or ‘have’ specifies a property, a region, a fixed number, a step, a process, an element and/or a component but does not exclude other properties, regions, fixed numbers, steps, processes, elements and/or components.

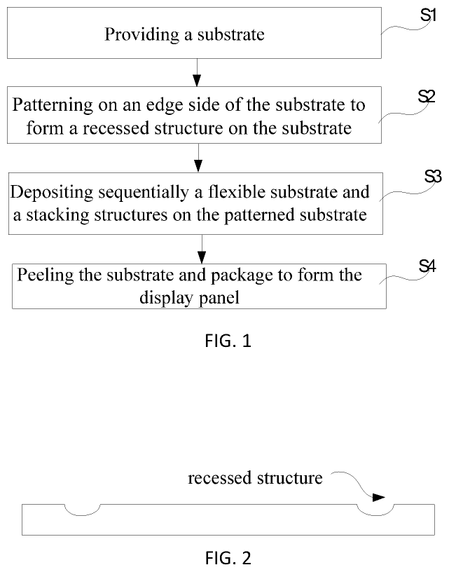

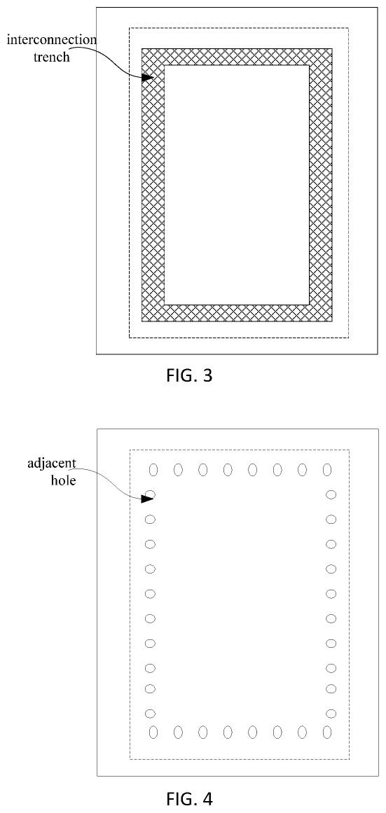

Refer to FIG. 1, FIG. 2, FIG. 3 and FIG. 4. FIG. 1 is a flow chart showing a manufacturing method of a display panel according to an embodiment of the present invention. FIG. 2 is a schematic diagram side view of a pattern formed on the substrate according to an embodiment of the present invention. FIG. 3 is a schematic diagram top view of a pattern formed on the substrate according to an embodiment of the present invention. FIG. 4 is a schematic diagram top view of a pattern formed on the substrate according to another embodiment of the present invention

S1, providing a substrate.

The substrate can be a translucent material. Specifically, the substrate can be glass, ceramic substrate or other translucent substrates made of different materials, but the present disclosure is not limited thereto. In this embodiment, the substrate is glass substrate.

S2, patterning on an edge side of the substrate to form a recessed structure on the substrate.

In this embodiment, patterning on an edge side of the substrate to form a recessed structure by laser etching, as shown on FIG. 2. Furthermore, the recessed structure is an interconnection trench by laser etching, as shown on FIG. 3. The interconnection trench is square-shaped in this embodiment, but the present disclosure is not limited thereto. For example, in other embodiments of the present disclosure, the interconnection trench can be circular-shaped, oval-shaped, diamond-shaped or polygon-shaped. The interconnection trench has adjustable width for corresponding to a projection portion of the flexible substrate. In particular, if the area of the projection portion of the flexible substrate is large, the width of the interconnection trench is wider for flatting the flexible substrate. Otherwise, if the area of the projection portion of the flexible substrate is small, the width of the interconnection trench is narrowed for flatting the flexible substrate.

In another embodiment of present invention, the recessed structure can be a plurality of adjacent hole, as shown on FIG. 4. The recessed structure is adjacent round holes in this embodiment, but the present disclosure is not limited thereto. For example, in other embodiments of the present disclosure, the recessed structure is square holes, oval holes. The size of the round holes and the spacing between two adjacent round holes can be adjustable for corresponding to the projection portion of the flexible substrate. In particular, if the area of the projection portion of the flexible substrate is large, the spacing between two adjacent round holes is adjusted to be dense or to increase the size of each round holes for improve the flexible substrate flatly. Otherwise, if the area of the projection portion of the flexible substrate is small, the spacing between two adjacent round holes is adjusted to be large or to decrease the size of each round holes for improve the flexible substrate flatly. The adjustment method of the adjacent holes are not limited thereto in the present invention, just only enhance the flatly of the flexible substrate.

In other embodiment, the recessed structure can also be alternately provided the interconnection trench and plurality of adjacent hole described above. Or, the recessed structure can be half of the interconnection trench and half of plurality of adjacent hole, but the present disclosure is not limited thereto.

In addition to etching the substrate by using laser etching, wet-chemical etching also can form the recessed structure on the substrate. The processing of etching is similar to the laser etching described above.

S3, depositing sequentially a flexible substrate and a stacking structures on the patterned substrate.

Depositing a flexible substrate on the patterned substrate after the step S2. The flexible substrate is selectively made by polyimide (PI) or polyethylene terephthalate, (PET). The flexible substrate is polyimide (PI) in this embodiment. The edge of the substrate warpage will not be happened while the PI depositing thereon which because the pattern are formed on the substrate. Comparing to the double PI layer structure, this manufacture also can reduce one step for coating a PI layer and still provide effective of PI layer planarization. Enhance the stability and the yield of the flexible display device and let the manufacture method more easily.

Further, a stacking structures is depositing on the flexible substrate. The stacking structures may include any of the existing display structures, for example, LED, OLED, LCD, EL and so on. In an embedment of the present invention, the stacking structures comprising an active array layer and an organic emission layer.

The active array layer can be prepared by a manufacture methods know in the art. The manufacture process flow described as below. Depositing sequentially a blocking layer, a buffer layer, an active layer, a grid insulation layer, a dielectric layer and a passivation layer on the flexible substrate to form the active array layer. The blocking layer and the buffer layer are selectively made of SiNx or SiO2. The blocking layer and the buffer layer also can make by other materials, the present disclosure is not limited thereto.

The organic emission layer is display medium of OLED in this embodiment of the present invention. The organic emission layer comprising a planarization layer, a pixel definition layer and pixel of OLED.

S4, peeling the substrate and package to form the display panel.

Peeling the substrate and package the substrate to form the display panel after depositing the stacking structures described above Step S3. Further, disposing a protective layer on a encapsulate layer after package process, and executing the bending processing and test the packaged display panel finally.

The advantages of the instant disclosure provide a recessed structure is disposed on the edge side of the substrate, the recessed structure offset warpage of the edge side of the flexible substrate and let the surface which faraway the substrate of the flexible substrate are more flat. And the film uniformity of the flexible substrate so that enhance the stability and the yield of the flexible display device. Comparing to the structure of double PI layer, this manufacture method can reduce one step for coating the PI layer, and let the manufacture method more easily.

Refer to FIG. 5. FIG. 5 is a schematic diagram of a display panel according to a embodiment of the present invention. The display panel 10 as shown FIG. 5 comprising, a flexible substrate 12, a stacking structures 13 and a encapsulate layer 14.

A downwardly projection portion A disposed on the edge side of the flexible substrate 12, and the downwardly projection portion A can be a connected projection portion or an interval projection portion. The downwardly projection portion A is corresponding to the recessed structure of the display panel of the present invention. The flexible substrate is selectively made by polyimide (PI) or polyethylene terephthalate, (PET). The flexible substrate is polyimide (PI) in this embodiment.

A stacking structures 13 is depositing on the flexible substrate 12, and further comprising an active array layer 131 and an organic emission layer.

The active array layer 131 further comprising: a blocking layer 1311, a buffer layer 1312, a grid insulation layer 1313, 1314, an inter-insulation layer 1315 and planarization layers 1316. The blocking layer 1311 and the buffer layer 1312 are selectively made of SiNx or SiO2. The blocking layer 1311 and the buffer layer 1312 also can make by other materials, the present disclosure is not limited thereto.

The organic emission layer further comprising: a pixel definition layer 1322 and pixel of OLED (not shown).

The encapsulate layer 14 is formed on the stacking structures 13 and further comprising a protective layer 141.

Please see the detail of the manufacture method and the principle of the structure of the embodiment as described above.

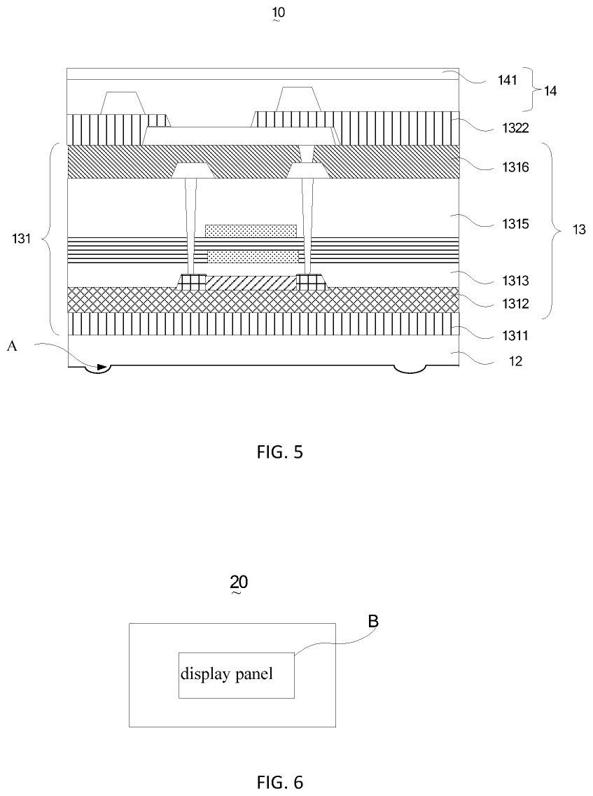

Refer to FIG. 6. FIG. 6 is a schematic diagram of a display device according to an embodiment of the present invention. The display device 20 comprising any one of the display panel B described above, and the detail of manufacture process and structure of the display panel B also described above.

According to the embodiment of the invention, a recessed structure is provided on the edge side of the substrate, the recessed structure offset warpage of the edge side of the flexible substrate for the surface which faraway the substrate of the flexible substrate are more flat. And the film uniformity of the flexible substrate so that enhance the stability and the yield of the flexible display device. Comparing to the structure of double PI layer this structure can reduce one step for coating the PI layer, and let the manufacture method more easily.

In sum, the skill in the art easily understand, the invention provide a display panel and the manufacture method thereof, a display device. A recessed structure is provided on the edge side of the substrate, the recessed structure offset warpage of the edge side of the flexible substrate make the surface which faraway the substrate of the flexible substrate are more flat. And the film uniformity of the flexible substrate so that enhance the stability and the yield of the flexible display device. Comparing to the structure of double PI layer this invention can reduce one step for coating the PI layer, and let the manufacture method more easily.

The descriptions illustrated supra set forth simply the preferred embodiments of the present disclosure; however, the characteristics of the present disclosure are by no means restricted thereto. All changes, alterations, or modifications conveniently considered by those skilled in the art are deemed to be encompassed within the scope of the present disclosure delineated by the following claims.

What is claimed is:

1. A manufacturing method of a display panel of a display device, comprising the steps of:
providing a substrate;
patterning on an edge side of the substrate to form a recessed structure on the substrate; and
depositing sequentially a flexible substrate and a stacking structures on the patterned substrate, the stacking structures comprising an active array layer and an organic emission layer are deposited sequentially on the flexible substrate, and the flexible substrate is selectively made of polyimide or polyethylene terephthalate.

2. The display device of claim 1, wherein the recessed structure comprising at least one of an interconnection trench or a plurality of adjacent hole.

3. The display device of claim 2, wherein the interconnection trench has adjustable width.

4. The display device of claim 2, wherein an amount of the hole and a spacing between the adjacent holes are adjustable.

5. The display device of claim 1, wherein the step of patterning on an edge side of the substrate by laser etching or wet-chemical etching.

6. A manufacturing method of a display panel, comprising the steps of:
providing a substrate;
patterning on an edge side of the substrate to form a recessed structure on the substrate;
depositing sequentially a flexible substrate and a stacking structures on the patterning substrate; and
peeling the substrate and packaging to form the display panel.

7. The manufacturing method of claim 6, wherein the recessed structure comprising at least one of an interconnection trench or a plurality of adjacent hole

8. The manufacturing method of claim 7, wherein the interconnection trench has adjustable width.

9. The manufacturing method of claim 7, wherein an amount of the hole and a spacing between the adjacent hole are adjustable

10. The manufacturing method of claim 7, wherein the flexible substrate is selectively made of polyimide or polyethylene terephthalate.

11. The manufacturing method of claim 6, wherein the step of patterning on an edge side of the substrate by laser etching or wet-chemical etching.

12. The manufacturing method of claim 6, wherein the stacking structures comprising an active array layer and an organic emission layer depositing sequentially on the flexible substrate.

13. A flexible display panel comprising:
a flexible substrate has a downwardly projection portion on an edge side,
a stacking structures forming on the flexible substrate; and
an encapsulating layer forming on the stacking structures.
